(19) United States
(12) Patent Application Publication
(10) Pub. No.: US 2015/0014662 A1
(43) Pub. Date: Jan. 15, 2015

(54) METHOD FOR PIXEL ARRANGEMENT AND DISPLAY PANNEL USING THE SAME

(71) Applicant: EverDisplay Optronics (Shanghai) Limited, Shanghai (CN)

(72) Inventors: TianWang Huang, Shanghai (CN); ChienLin Wu, Shanghai (CN)

(21) Appl. No.: 14/329,163

(22) Filed: Jul. 11, 2014

(30) Foreign Application Priority Data
Jul. 11, 2013 (CN) 201310292428.3

(51) Int. Cl. H01L 27/32; H01L 51/56

(52) U.S. Cl. CPC H01L 27/3262; H01L 27/3218; H01L 51/56
USPC 257/40; 438/66

(57) ABSTRACT

One embodiment of the present invention discloses a method for pixel arrangement and a display using the same. The display areas are divided into a plurality of rectangular regions which have the same area according to a plurality of vertical grids which own the same distance between the adjacent. According to pre-positioning horizontal axis lines and pre-positioning vertical axis lines, each of the rectangular regions is divided into four parts including an upper left part, an upper right part, a lower left part and a lower right part. Each of the four parts are divided into two sub-pixel areas by a line which is inside the part. The line connects the angle point of the region which the part belongs to and the cross point of the horizontal axis line and the vertical axis line of the region which the part belongs to.

### CROSS-REFERENCE TO RELATED APPLICATIONS

The present application claims priority to and the benefit of Chinese Patent Application No. CN 201310292428.3, filed on Jul. 11, 2013, the entire content of which is incorporated herein by reference.

### BACKGROUND OF THE INVENTION

1. Field of the Invention

The present disclosure is related to the technology of pixel arrangement, more specifically, to a method for pixel arrangement and a display using the same.

2. Description of the Related Art

OLED, i.e., Organic Light-Emitting Diode, is also named as Organic Electroluminescence Display. OLED owns a character of self-luminous, which is achieved by the light-emitting of thin organic material coatings on the glass substrate where the current passing. The visual angle of OLED display screen is large and the electric energy could be economized greatly. Hence, OLED owns some advantages that other display screens do not have.

However, due to the limitation of the manufacturing art of OLED, the resolution ratio of the image (PPI) displayed by OLED display screens is hard to increase, which becomes the choke point in the OLED development.

As shown in FIG. 1, the present display generally adopts the arrangement of side by side for RGB pixels, that is a pixel consists of three sub-pixels displaying red color, green color and blue color respectively. However, such pixel arrangement applied to OLED may cause the color mixture problem in the vapor deposition process, which will decrease the yield of products.

According to the character of OLED, a pixel arrangement named as “Pen Tile” is adopted as shown in FIG. 2, which is of benefit to the improvement the yield of OLED panel, however the resolution ratio is ⅔ of which is arranged side by side. Therefore, it is easy to cause the color cast problem, which is not of benefit to the performance of OLED.

### SUMMARY OF THE INVENTION

An aspect of an embodiment of the present disclosure is directed toward a method for pixel arrangement capable of reducing the area occupied by the sub-pixels in unit space, increasing the physical resolution, achieving Higher NTSC, and reducing the power dissipation of the display.

Another aspect of an embodiment of the present disclosure is directed toward for a display.

An embodiment of the present disclosure provides a method for pixel arrangement in a display having a display area, comprising:

dividing said display area into a plurality of rectangular regions adjacent to each other, each said rectangular region has substantially the same area;

dividing each of the rectangular regions into eight sub-pixel areas with triangular shape having substantially the same area; and

arranging a plurality of pixels over said display area, said plurality of pixels comprise a first type of pixel and a second type of pixel, said first type of pixel and said second type of pixel are in different shapes;

wherein said each of said first type of pixel comprises four sub-pixels in one of said rectangular regions and each of said second type of pixel comprises four sub-pixels and is arranged in an interval between two adjacent said first type of pixels.

According to one embodiment of the present disclosure, wherein said first type of pixel comprises two triangular shapes, said two triangular shapes are point-symmetric.

According to one embodiment of the present disclosure, wherein said second type of pixel comprises four sub-pixels forming a substantially square shape.

According to one embodiment of the present disclosure, wherein a plurality of light-emitting devices are formed in said sub-pixel areas.

According to one embodiment of the present disclosure, wherein said plurality of light-emitting devices are organic light-emitting devices.

According to one embodiment of the present disclosure, wherein said display is an organic light-emitting display.

According to one embodiment of the present disclosure, wherein said four sub-pixels of said first type of pixel comprise two sub-pixels with blue color, one sub-pixel with red color and one sub-pixel with green color.

According to one embodiment of the present disclosure, said four sub-pixels of said second type of pixel comprise two sub-pixels with blue color, one sub-pixel with red color and one sub-pixel with green color.

According to one embodiment of the present disclosure, wherein said two sub-pixels with blue color are arranged along a vertical direction.

According to one embodiment of the present disclosure, wherein said two sub-pixels with blue color are arranged along a vertical direction.

Another embodiment of the present disclosure provides a display having a display area, comprising:

a plurality of rectangular regions adjacent to each other and arranged in said display area, each said rectangular region having substantially the same area, and each of the rectangular regions comprising eight sub-pixel areas with triangular shape having substantially the same area; and

a plurality of pixels arranged over said display area, said plurality of pixels comprising a first type of pixel and a second type of pixel, said first type of pixel and said second type of pixel are in different shapes;

wherein, said each of said first type of pixel comprises four sub-pixels in one of said rectangular regions and each of said second type of pixel comprises four sub-pixels and is arranged in an interval between two adjacent said first type of pixels.

According to another embodiment of the present disclosure, wherein said first type of pixel comprises two triangular shapes, said two triangular shapes are point-symmetric.

According to another embodiment of the present disclosure, wherein said second type of pixel comprises four sub-pixels forming a substantially square shape.

According to another embodiment of the present disclosure, wherein a plurality of light-emitting devices are formed in said sub-pixel areas.

According to another embodiment of the present disclosure, wherein said plurality of light-emitting devices are organic light-emitting devices.

According to another embodiment of the present disclosure, wherein said display is an organic light-emitting display.

According to another embodiment of the present disclosure, wherein said four sub-pixels of said first type of pixel comprise two sub-pixels with blue color, one sub-pixel with red color and one sub-pixel with green color.

According to another embodiment of the present disclosure, said four sub-pixels of said second type of pixel comprise two sub-pixels with blue color, one sub-pixel with red color and one sub-pixel with green color.

According to another embodiment of the present disclosure, wherein said two sub-pixels with blue color are arranged along a vertical direction.

According to another embodiment of the present disclosure, wherein said two sub-pixels with blue color are arranged along a vertical direction.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a schematic view of side by side sub-pixel arrangement of the display in the related art;

FIG. 2 shows a schematic view of Pen tile sub-pixel arrangement of the display in the related art;

FIG. 3 shows a schematic view of RGBB sub-pixel arrangement of the display in the related art;

FIG. 4 shows a structure schematic of the four parts of the rectangular region arranged by the method according to an embodiment of the present invention;

FIG. 5 shows a structure schematic of the eight sub-pixel area divided from the four parts of the rectangular region arranged by the method according to an embodiment of the present invention;

FIG. 6 shows a structure schematic of the union of two sub-pixel units in two adjacent rectangular regions arranged by the method according to an embodiment of the present invention;

FIG. 7 shows a structure schematic of the first type pixel unit according to an embodiment of the present invention;

FIG. 8 shows a structure schematic of the second type pixel unit according to an embodiment of the present invention;

FIG. 9 shows a structure schematic of the first type pixel unit and the second type pixel unit which are arranged crisscross in horizontal direction according to an embodiment of the present invention;

FIG. 10 shows a structure schematic of the first type pixel unit and the second type pixel unit which cover parts of the display area through a horizontal cross arrangement according to the present invention;

FIG. 11 shows a structure schematic of the first type pixel unit and the second type pixel unit which are arranged crisscross in vertical direction according to an embodiment of the present invention;

FIG. 12 shows a structure schematic according to the first exemplary embodiment of the present invention;

FIG. 13 shows a structure schematic according to the second exemplary embodiment of the present invention.

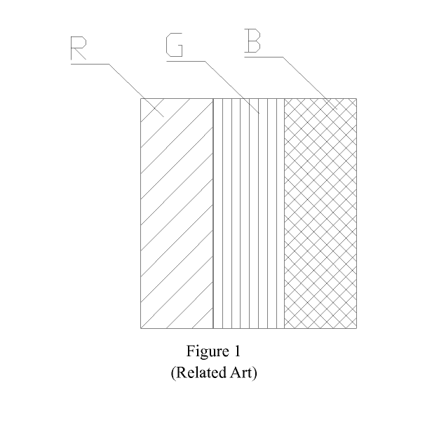

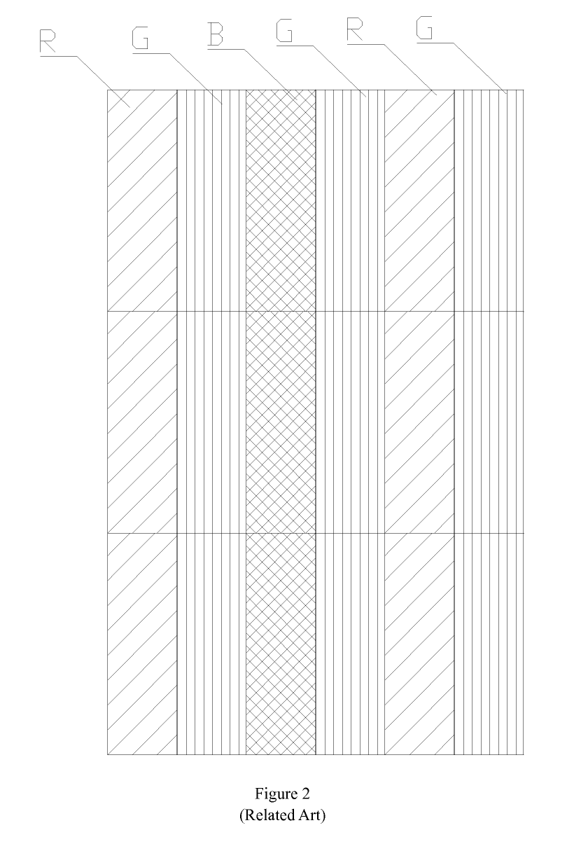

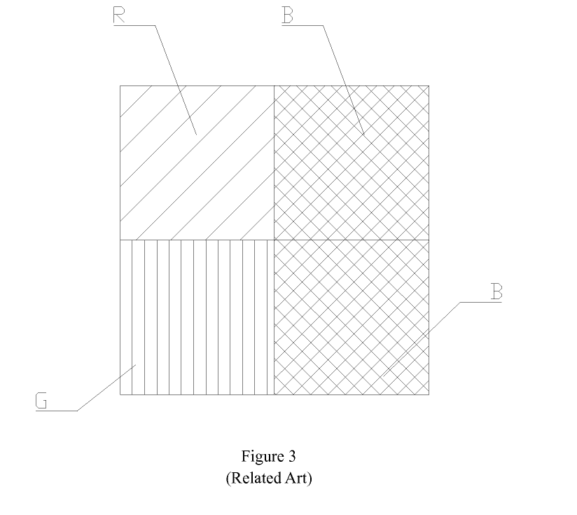

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

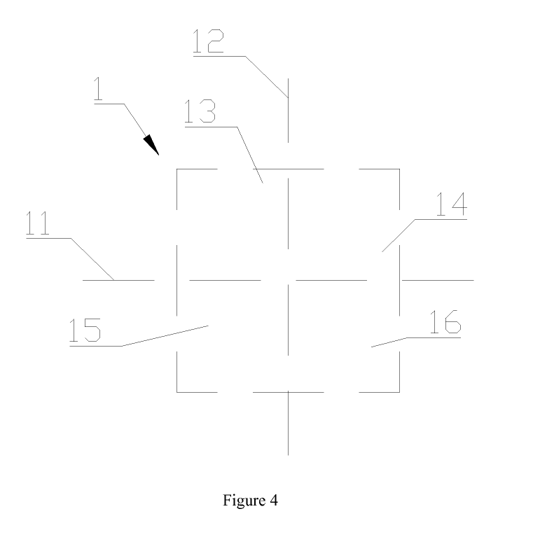

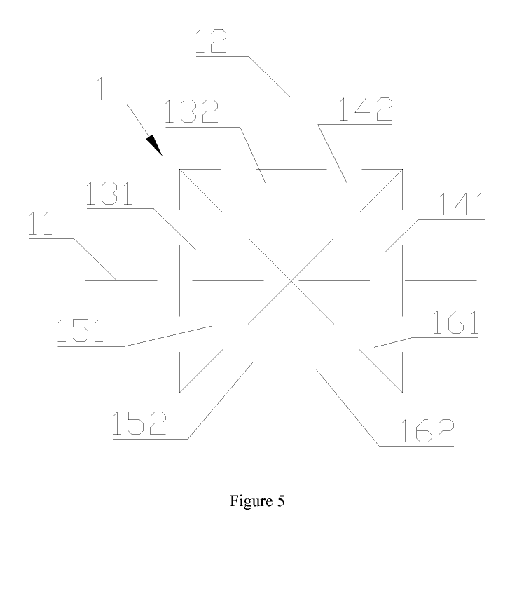

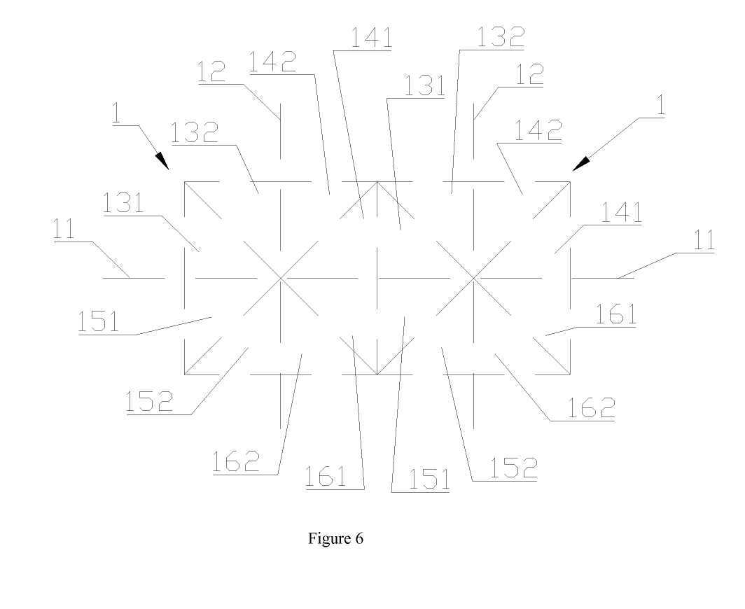

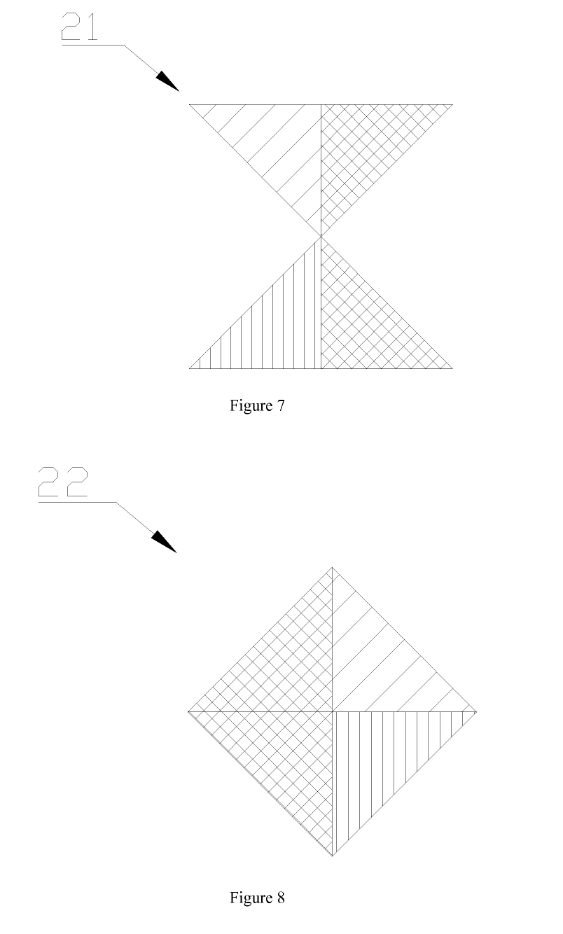

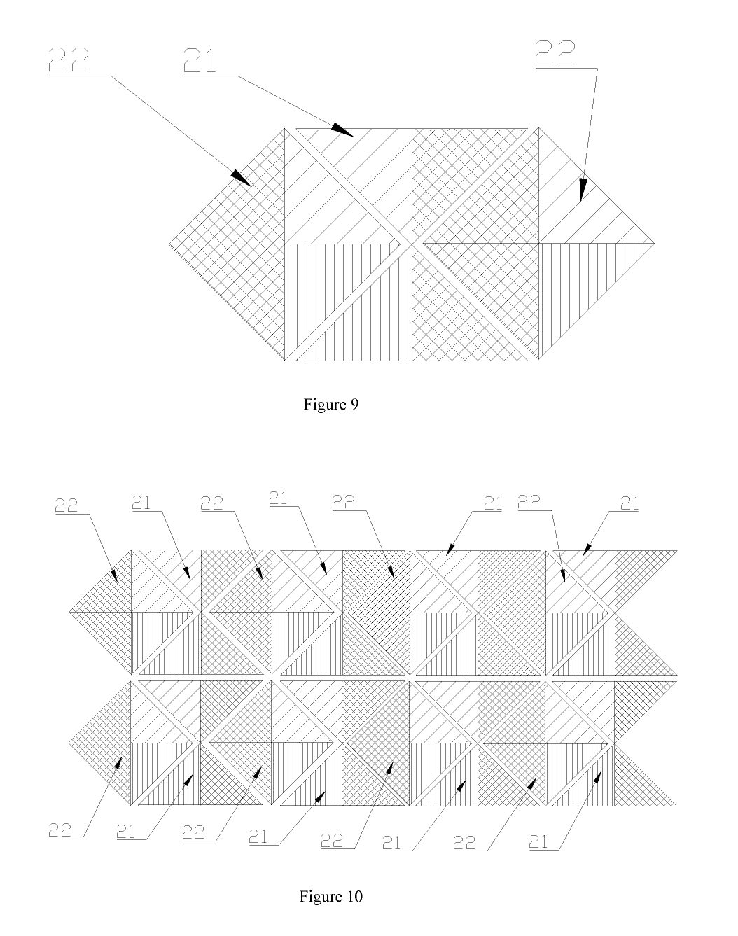

As shown in FIGS. 4 to 10, a method for pixel arrangement is provided. The display areas are divided into a plurality of Rectangular Regions 1 which have the same areas according to a plurality of vertical grids which own the same distance between the adjacent. According to pre-positioning Horizontal Axis Lines 11 and pre-positioning Vertical Axis Lines 12, each of Rectangular Regions 1 is divided into four parts including an Upper Left Part 13, an Upper Right Part 14, a Lower Left Part 15 and a Lower Right Part 16. Each of the four parts is divided into two sub-pixel areas by a line which is inside the part. The line connects the angle point of the region which the part belongs to and the cross point of Horizontal Axis Line 11 and Vertical Axis Line 12 of the region which the part belongs to. The four parts of each rectangular regions are divided into eight sub-pixel areas.

Upper Left Part 13 is divided into a First Upper Left Sub-Pixel Area 131 which has the common edge with Horizontal Axis Line 11 and the line vertical to Rectangular Region 1 including Upper Left Part 13, and a Second Upper Left Sub-Pixel Area 132 which has the common edge with Vertical Axis Line 12 and the line horizontal to Rectangular Region 1 including Upper Left Part 13;

Upper Right Part 14 is divided into a First Upper Right Sub-Pixel Area 141 which has the common edge with Horizontal Axis Line 11 and the line vertical to Rectangular Region 1 including Upper Right Part 14, and a Second Upper Right Sub-Pixel Area 142 which has the common edge with Vertical Axis Line 12 and the line horizontal to Rectangular Region 1 including Upper Right Part 14.

Lower Left Part 15 is divided into a First Lower Left Sub-Pixel Area 151 which has the common edge with Horizontal Axis Line 11 and the line vertical to Rectangular Region 1 including the Lower Left Part 15, and a Second Lower Left Sub-Pixel Area 152 which has the common edge with Vertical Axis Line 12 and the line horizontal to Rectangular Region 1 including Lower Left Part 15.

Lower Right Part 16 is divided into a First Lower Right Sub-Pixel Area 161 which has the common edge with the Horizontal Axis Line 11 and the line vertical to Rectangular Region 1 including the Lower Right Part 16, and a Second Lower Right Sub-Pixel Area 162 which has the common edge with Vertical Axis Line 12 and the line horizontal to Rectangular Region 1 including Lower Right Part 16.

Light-emitting devices are arranged in each sub-pixel area.

The light-emitting devices which are in Second Upper Left Sub-Pixel Area 132, in Second Upper Right Sub-Pixel Area 142, in Second Lower Left Sub-Pixel Area 152 and in Second Lower Right Sub-Pixel Area 162 of each Rectangular Region 1 consist a First Type Pixel Unit 21.

The light-emitting devices, which are in First Upper Left Sub-Pixel Area 131 and the First Lower Left Sub-Pixel Area 151 of each Rectangular Region 1, and which are in First Upper Right Sub-Pixel Area 141 and First Lower Right Sub-Pixel Area 161 of the rectangular left adjacent to the rectangular region, consist a Second Type Pixel Unit 22.

The light-emitting devices, which are in the First Upper Right Sub-Pixel Area 141 and First Lower Right Sub-Pixel Area 161 of each Rectangular Region 1, and which are in First Lower Left Sub-Pixel Area 151 and First Upper Left Sub-Pixel Area 131 of the rectangular right adjacent to the Rectangular Region 1, consist a Second Type Pixel Unit 22.

First Type Pixel Unit 21 and Second Type Pixel Unit 22 are arranged crisscross in horizontal direction, and align each other between First Type Pixel Unit 21 in vertical direction; Second Type Pixel Unit 22 align each other in vertical direction and covers the entire display area.

The above technical solution adopts the sub-pixel arrangement which is presented as a triangle, which increases the number of the sub-pixels in the whole display areas. When the area is fixed, the number of the sub-pixels in the triangular sub-pixel areas is 8/3 times of that arranged by the current RGB arrangement, or is twice of that arranged by the current RGBB arrangement. When the number of the sub-pixels in a pixel unit is fixed, the image resolution will be improved through the arrangement in the above technical solution.

The above technical solution indicated an embodiment that First Type Pixel Unit 21 and Second Type Pixel Unit 22 covers the whole display areas through being arranged crisscross in horizontal direction. As shown in FIG. 11, the light-emitting devices which are in First Upper Left Sub-Pixel Area 131, in First Upper Right Sub-Pixel Area 141, in First Lower Left Sub-Pixel Area 151 and in First Lower Right Sub-Pixel Area 161 of each Rectangular Region 1 consist a First Type Pixel Unit 21; the light-emitting devices, which are in Second Upper Left Sub-Pixel Area 132 and the Second Upper Right Sub-Pixel Area 142 of each Rectangular Region 1, and which are in Second Lower Left Sub-Pixel Area 152 and Second Lower Right Sub-Pixel Area 162 of the rectangular upward adjacent to the rectangular region, consist a Second Type Pixel Unit 22; the light-emitting devices, which are in the Second Lower Left Sub-Pixel Area 152 and Second Lower Right Sub-Pixel Area 162 of each Rectangular Region 1, and which are in Second Upper Left Sub-Pixel Area 132 and Second Upper Right Sub-Pixel Area 142 of the rectangular right adjacent to Rectangular Region 1, consist a Second Type Pixel Unit 22; First Type Pixel Unit 21 and Second Type Pixel Unit 22 are arranged crisscross in vertical direction, and align each other between First Type Pixel Unit 21 in horizontal direction; Second Type Pixel Unit 22 align each other in horizontal direction and covers the entire display area.

Based on the above technical solution, further, Horizontal Axis Line 11 is the horizontal central axis line of Rectangular Region 1. Moreover, Vertical Axis Line 12 is the vertical central axis line of Rectangular Region 1. Simultaneously, Rectangular Region 1 could be divided into squares. The arrangement of Rectangular Region 1 could be determined according to the requirement. Meanwhile, the ways for dividing Rectangular Region 1 into four parts also could be adjusted according the requirement of the light-emitting devices which need to be arranged in the four parts. The core idea of the embodiment in the present invention is that the four parts of Rectangular Region 1 is divided into eight triangular sub-pixel areas according to the diagonal lines which direct to the centre of Rectangular Region 1, which increases the number of the sub-pixels in the unit area. Hence, any means of dividing based on the above core idea should be included in the solutions of the present invention. The two exemplary embodiments of dividing Rectangular Region 1 will be provided and illustrated in the following contents.

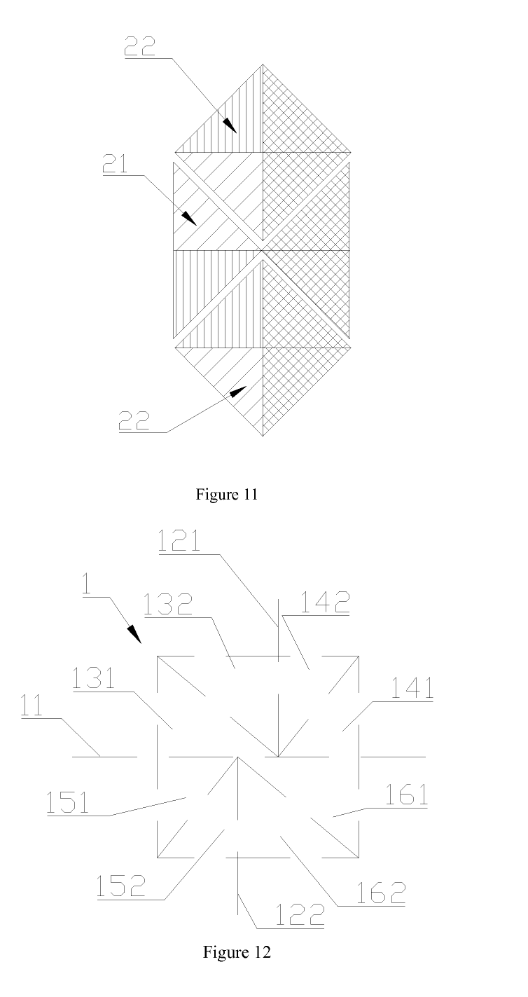

The first dividing method as shown in FIG. 12, each Rectangular Region 1 is divided into four parts including an Upper Left Part 13, an Upper Right Part 14, a Lower Left Part 15 and a Lower Right Part 16 by the lines which are the pre-positioning Horizontal Axis Line 11, a First Vertical Half Axis Line 121 located above and vertical to Horizontal Axis Line 11, and a Second Vertical Half Axis Line 122 located below and vertical to Horizontal Axis Line 11; dividing the four parts of each Rectangular Region 1 into eight sub-pixel areas though dividing each of the four parts into two sub-pixel areas by Horizontal Axis Line 11 which is inside the part and connects the angle point of the region which the part belongs to and the cross point of the First Vertical Half Axis Line 121 and Second Vertical Half Axis Line 122 of the region which the part belongs to; Upper Left Part 13 is divided into a First Upper Left Sub-Pixel Area 131 which has the common edge with Horizontal Axis Line 11 and the line vertical to Rectangular Region 1 including Upper Left Part 13, and a Second Upper Left Sub-Pixel Area 132 which has the common edge with First Vertical Half Axis Line 121 and the line horizontal to Rectangular Region 1 including Upper Left Part 13; Upper Right Part 14 is divided into a First Upper Right Sub-Pixel Area 141 which has the common edge with Horizontal Axis Line 11 and the line vertical to Rectangular Region 1 including Upper Right Part 14, and a Second Upper Right Sub-Pixel Area 142 which has the common edge with First Vertical Half Axis Line 121 and the line horizontal to Rectangular Region 1 including Upper Right Part 14; Lower Left Part 15 is divided into a First Lower Left Sub-Pixel Area 151 which has the common edge with Horizontal Axis Line 11 and the line vertical to the Rectangular Region 1 including Lower Left Part 15, and a Second Lower Left Sub-Pixel Area 152 which has the common edge with Second Vertical Half Axis Line 122 and the line horizontal to Rectangular Region 1 including Lower Left Part 15; Lower Right Part 16 is divided into a First Lower Right Sub-Pixel Area 161 which has the common edge with Horizontal Axis Line 11 and the line vertical to Rectangular Region 1 including Lower Right Part 16, and a Second Lower Right Sub-Pixel Area 162 which has the common edge with Second Vertical Half Axis Line 122 and the line horizontal to the Rectangular Region 1 including Lower Right Part 16.

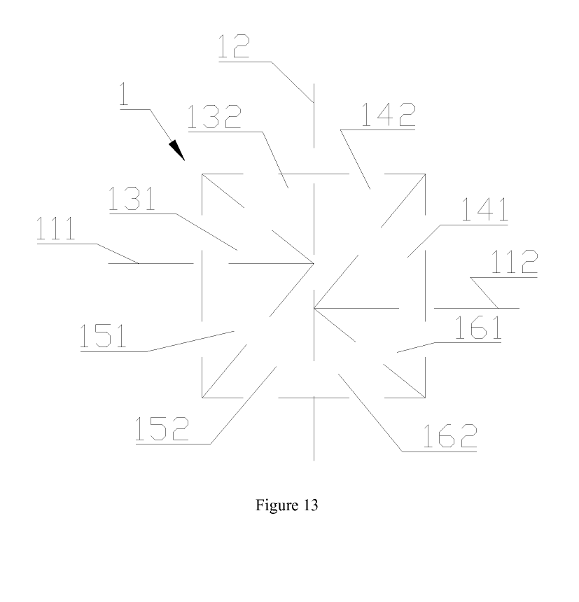

The second dividing method as shown in FIG. 13, each of the Rectangular Region 1 are divided into four parts including an Upper Left Part 13, an Upper Right Part 14, a Lower Left Part 15 and a Lower Right Part 16 according to pre-positioning Vertical Axis Lines 12 and a First Horizontal Half Axis Line 111 located at a preset position left to and vertical to Vertical Axis Lines 12; the four parts of each Rectangular Region 1 are divided into eight sub-pixel areas through dividing each of the four parts are divided into two sub-pixel areas by a Vertical Axis Lines 12 which is inside the part and connects the angle point of the region which the part belongs to and the cross point of First Horizontal Half Axis Line 111 and Second Horizontal Half Axis Line 112 of the region which the part belongs to; Upper Left Part 13 is divided into a First Upper Left Sub-Pixel Area 131 which has the common edge with First Horizontal Half Axis Line 111 and the line vertical to Rectangular Region 1 including Upper Left Part 13, and a Second Upper Left Sub-Pixel Area 132 which has the common edge with Vertical Axis Lines 12 and the line horizontal to Rectangular Region 1 including Upper Left Part 13; Upper Right Part 14, is divided into a First Upper Right Sub-Pixel Area 141 which has the common edge with the Second Horizontal Half Axis Line 112 and the line vertical to Rectangular Region 1 including Upper Right Part 14, and a Second Upper Right Sub-Pixel Area 142 which has the common edge with Vertical Axis Lines 12 and the line horizontal to Rectangular Region 1 including Upper Right Part 14; Lower Left Part 15 is divided into a First Lower Left Sub-Pixel Area 151 which has the common edge with First Horizontal Half Axis Line 111 and the line vertical to Rectangular Region 1 including Lower Left Part 15, and a Second Lower Left Sub-Pixel Area 152 which has the common edge with Vertical Axis Lines 12 and the line horizontal to Rectangular Region 1 including Lower Left Part 15; Lower Right Part 16 is divided into a First Lower Right Sub-Pixel Area 161 which has the common edge with Second Horizontal Half Axis Line 112 and the line vertical to Rectangular Region 1 including Lower Right Part 16, and a Second Lower Right Sub-Pixel Area 16 which has the common edge with Vertical Axis Lines 12 and the line horizontal to Rectangular Region 1 including the Lower Right Part 16.

The above two embodiment of dividing the rectangular region is used for illustrating the method more visually, not the limitation of the present invention. Simultaneously, the above two dividing ways and the above mentioned dividing ways are adopted to the embodiment that First Type Pixel Unit 21 and Second Type Pixel Unit 22 are arranged crisscross in horizontal direction, and adopted to the embodiment that First Type Pixel Unit 21 and Second Type Pixel Unit 22 are arranged crisscross in vertical direction.

What needs to be illustrated is that the above mentioned objects including vertical grid, Horizontal Axis Lines 12, Vertical Axis Lines 12, First Horizontal Half Axis Line 111, Second Horizontal Half Axis Line 112, First Vertical Half Axis Line 121, Second Vertical Half Axis Line 122 and Rectangular Region 1 are all the logical lines. Parts or all of the logical lines could be arranged in the device whose pixels are arranged by the above solution, or could be used in the processes of arranging the pixels to assist the production of the device. The ways of the logical lines in the processes could be hypostatic connection or the liner control way in logical.

Based on the above solution, further, the colors of the light-emitting devices located in two sub-pixel areas of one part of Rectangular Region 1 are identical, which is of benefit to produce OLED. The light-emitting devices with at least three colors are arranged in the four parts of each Rectangular Region 1, and the light-emitting devices which emit light with different colors are arranged in the same place of its rectangular region, and light-emitting devices. The light-emitting devices with at least three colors makes it possible to achieve RGB display, in the present invention, it is possible to arrange more colors to meet the requirements of other display ways. Based on this, the devices emitting the lights with the same color are arranged in Upper Right Part 14 and Lower Right Part 16 of Rectangular Region 1, or the devices emitting the lights with the same color are arranged in Upper Left Part 13 and Lower Left Part 15, which makes it possible to achieve RGBB display to solve the problem that the light-emitting device emitting blue light is easy to be broken.

Based on the above solution, further, the shape of the light-emitting device arranged in each sub-pixel area are identical to that of the sub-pixel area, which is of benefit to take full advantage of the space of the display area to improve the image resolution. Certainly, the light-emitting device whose shape is different from that of the sub-pixel area are also included in the present invention, for instance, the light-emitting devices with arch shape or the light-emitting devices with oval shape and divided into two parts can be arranged in each sub-pixel area, that is the light-emitting devices in each part of Rectangular Region 1 together form the shape of circle and oval.

What to be illustrated is that the above solution is applicable to the display devices formed by organic light-emitting devices, and is applicable to the display devices formed by other devices.

Furthermore, the ratio between the number of the horizontal pixel units in the display and the number of the vertical pixel units in the display is 4:3 or 16:9.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method for pixel arrangement in a display having a display area, comprising:
dividing said display area into a plurality of rectangular regions adjacent to each other, each said rectangular region has substantially the same area;
dividing each of the rectangular regions into eight sub-pixel areas with triangular shape having substantially the same area; and
arranging a plurality of pixels over said display area, said plurality of pixels comprise a first type of pixel and a second type of pixel, said first type of pixel and said second type of pixel are in different shapes;
wherein each of said first type of pixel comprises four sub-pixels in one of said rectangular regions and each of said second type of pixel comprises four sub-pixels and is arranged in an interval between two adjacent said first type of pixels.

2. The method for pixel arrangement in a display as claimed in claim 1, wherein said first type of pixel comprises two triangular shapes, said two triangular shapes are point-symmetric.

3. The method for pixel arrangement in a display as claimed in claim 1, wherein said second type of pixel comprises four sub-pixels forming a substantially square shape.

4. The method for pixel arrangement in a display as claimed in claim 1, wherein a plurality of light-emitting devices are formed in said sub-pixel areas.

5. The method for pixel arrangement in a display as claimed in claim 1, wherein said plurality of light-emitting devices are organic light-emitting devices.

6. The method for pixel arrangement in a display as claimed in claim 5, wherein said display is an organic light-emitting display.

7. The method for pixel arrangement in a display as claimed in claim 1, wherein said four sub-pixels of said first type of pixel comprise two sub-pixels with blue color, one sub-pixel with red color and one sub-pixel with green color.

8. The method for pixel arrangement in a display as claimed in claim 1, said four sub-pixels of said second type of pixel comprise two sub-pixels with blue color, one sub-pixel with red color and one sub-pixel with green color.

9. The method for pixel arrangement in a display as claimed in claim 7, wherein said two sub-pixels with blue color are arranged along a vertical direction.

10. The method for pixel arrangement in a display as claimed in claim 8, wherein said two sub-pixels with blue color are arranged along a vertical direction.

11. A display having a display area, comprising:
a plurality of rectangular regions adjacent to each other and arranged in said display area, each said rectangular region having substantially the same area, and each of the rectangular regions comprising eight sub-pixel areas with triangular shape having substantially the same area; and
a plurality of pixels arranged over said display area, said plurality of pixels comprising a first type of pixel and a second type of pixel, said first type of pixel and said second type of pixel are in different shapes;
wherein, each of said first type of pixel comprises four sub-pixels in one of said rectangular regions and each of said second type of pixel comprises four sub-pixels and is arranged in an interval between two adjacent said first type of pixels.

12. The display as claimed in claim 11, wherein said first type of pixel comprises two triangular shapes, said two triangular shapes are point-symmetric.

13. The display as claimed in claim 11, wherein said second type of pixel comprises four sub-pixels forming a substantially square shape.

14. The display as claimed in claim 11, wherein a plurality of light-emitting devices are formed in said sub-pixel areas.

15. The display as claimed in claim 11, wherein said plurality of light-emitting devices are organic light-emitting devices.

16. The display as claimed in claim 15, wherein said display is an organic light-emitting display.

17. The display as claimed in claim 11, wherein said four sub-pixels of said first type of pixel comprise two sub-pixels with blue color, one sub-pixel with red color and one sub-pixel with green color.

18. The display as claimed in claim 11, said four sub-pixels of said second type of pixel comprise two sub-pixels with blue color, one sub-pixel with red color and one sub-pixel with green color.

19. The display as claimed in claim 17, wherein said two sub-pixels with blue color are arranged along a vertical direction.

20. The display as claimed in claim 18, wherein said two sub-pixels with blue color are arranged along a vertical direction.
